(19) United States
(12) Patent Application Publication
(10) Pub. No.: US 2025/0285856 A1
(43) Pub. Date: Sep. 11, 2025

(54) Doped Aluminum Oxide Bonding Layer for Hybrid Bonding

(71) Applicant: Applied Materials, Inc., Santa Clara, CA (US)

(72) Inventors: Joshua Stuart HOLT, Sunnyvale, CA (US); Mariia GORCHICHKO, San Jose, CA (US); Archana KUMAR, Mountain View, CA (US); Amit PRAKASH, Santa Clara, CA (US); Shubhendra Kumar JAIN, Belmont, MA (US); William Oghandi CHARLES, Winchester, MA (US); Roger Allan QUON, Rhinebeck, NY (US); Ryan Thomas LEY, Mountain View, CA (US); Stephen WEEKS, Morrisville, VT (US); Benjamin D. BRIGGS, Merrimack, NH (US); Yoocharn JEON, Palo Alto, CA (US)

(21) Appl. No.: 18/599,819

(22) Filed: Mar. 8, 2024

(51) Int. Cl. H01L 21/02; C23C 16/40; C23C 16/455; H01L 21/3215

(52) U.S. Cl. CPC H01L 21/02178; C23C 16/403; C23C 16/45525; H01L 21/3215

(57) ABSTRACT

A method for processing a substrate for hybrid bonding that includes doping an aluminum oxide (Al₂O₃) layer prior to bonding of the substrate. A method may include forming an aluminum oxide layer with a metal dopant to form a doped aluminum oxide layer on the substrate where the doped aluminum oxide forms a bonding layer for a hybrid bonding process on an uppermost surface of the substrate. A metal contact is formed on the substrate that penetrates through the doped aluminum oxide layer and a chemical mechanical polish (CMP) process is performed to recess an uppermost surface of the metal contact below a surface of the doped aluminum oxide layer.

### FIELD

Embodiments of the present principles generally relate to semiconductor processing of semiconductor substrates.

### BACKGROUND

Hybrid bonding is the joining or bonding of more than one type of material. In semiconductor manufacturing, hybrid bonding is used to package devices by bonding one substrate or die to another substrate or die to join not only dielectric surfaces but to also join metal interconnects or contacts together. Traditionally, dielectrics, such as silicon dioxide, provide most of the bonding strength in a hybrid bond. As the density of the interconnects and contacts increases, the dielectric material bonding area decreases. To help ensure a successful bond with a die or substrate with a high density of contacts, dielectric materials with higher bonding strengths, such as aluminum oxide, may be introduced into the manufacturing processes. However, the inventors have observed that during hybrid bonding processes that use aluminum oxide, poor bonding occurs between the metal interconnects and contacts, leading to low yields.

Accordingly, the inventors have provided methods for improving hybrid bonding performance of aluminum oxide-based substrates.

### SUMMARY

Methods for improving hybrid bonding performance by doping of aluminum oxides are provided herein.

In some embodiments, a method for processing a substrate may comprise providing a first substrate for a hybrid bonding process and forming, on the first substrate, a hybrid bonding layer that comprises a doped aluminum oxide (Al₂O₃) layer and a metal contact penetrating through the doped aluminum oxide layer.

In some embodiments, the method may further include hybrid bonding the first substrate to a second substrate via the hybrid bonding layer, a doped aluminum oxide layer that is doped with a metal dopant that has an atomic radius greater than an atomic radius of aluminum or oxygen, formation of a doped aluminum oxide layer that includes depositing an aluminum oxide layer in conjunction with the metal dopant, aluminum oxide and metal dopant that are co-sputtered using a physical vapor deposition (PVD) process to form the doped aluminum oxide layer with the metal dopant interspersed throughout, aluminum oxide and metal dopant that are deposited using an atomic layer deposition (ALD) process to form the doped aluminum oxide layer with the metal dopant interspersed throughout, metal dopant that is hafnium, zirconium, titanium, tungsten, or tantalum, an amount of the metal dopant in the doped aluminum oxide layer that is selected based on a temperature of an annealing process to be performed after a bonding process, a doped aluminum oxide layer that is an aluminum oxide layer that is formed first on the first substrate followed by a formation of the metal contact on the first substrate which penetrates through the aluminum oxide layer and then doped with a metal dopant throughout, doping of the aluminum oxide layer that is performed selectively only on the aluminum oxide layer, doping of the aluminum oxide layer that is performed on the aluminum oxide layer and on the metal contact, a doped aluminum oxide layer that is approximately 30 nm to approximately 50 nm in thickness, a doped aluminum oxide layer that has a leakage current of less than approximately 2× a leakage current of aluminum oxide or silicon dioxide, and/or a doped aluminum oxide layer that contains at least approximately 25% metal dopant.

In some embodiments, a substrate prepared for hybrid bonding may comprise a dielectric material, at least one metal contact, and a doped dielectric bonding layer surrounding the at least one metal contact where an uppermost surface of the at least one metal contact is exposed through the doped dielectric bonding layer.

In some embodiments, the substrate may further include a doped dielectric bonding layer that is a doped aluminum oxide (Al₂O₃) layer where at least one of the at least one metal contact is copper and where the doped aluminum oxide layer is doped with a metal dopant throughout, a metal dopant that is hafnium, zirconium, titanium, tungsten, or tantalum, and/or a device comprising the substrate another substrate that is hybrid bonded to the substrate via the doped dielectric bonding layer and the at least one metal contact.

In some embodiments, a non-transitory, computer readable medium having instructions stored thereon that, when executed, cause a method for processing a substrate, the method may comprise providing a substrate for a hybrid bonding process and forming, on the substrate, a hybrid bonding layer that comprises a doped aluminum oxide (Al₂O₃) layer and a metal contact penetrating through the doped aluminum oxide layer.

In some embodiments, the method of the non-transitory, computer readable medium may further include a doped aluminum oxide layer that has a leakage current of less than approximately 2× a leakage current of aluminum oxide or silicon dioxide, a doped aluminum oxide layer that is doped with a metal dopant and where an amount of the metal dopant in the doped aluminum oxide layer is selected based on a temperature of an annealing process to be performed after a bonding process, formation of a doped aluminum oxide layer that includes depositing an aluminum oxide layer on the substrate and doping the aluminum oxide layer with a metal dopant and/or formation of the doped aluminum oxide layer includes depositing an aluminum oxide layer in conjunction with a metal dopant.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method for preparing a substrate for hybrid bonding where metal contact formation occurs after doping procedures in accordance with some embodiments of the present principles.

FIG. 2 is a method for preparing a substrate for hybrid bonding where metal contact formation occurs before doping procedures in accordance with some embodiments of the present principles.

FIG. 3 depicts a cross-sectional view of a substrate in preparation for a hybrid bonding process in accordance with some embodiments of the present principles.

FIG. 4 depicts a cross-sectional view of a substrate with a doped aluminum oxide bonding layer in accordance with some embodiments of the present principles.

FIG. 5 depicts a cross-sectional view of an aluminum oxide bonding layer being doped with a metal dopant in accordance with some embodiments of the present principles.

FIG. 6 depicts a cross-sectional view of a substrate with a metal contact formed through a doped aluminum oxide bonding layer in accordance with some embodiments of the present principles.

FIG. 7 depicts a cross-sectional view of a substrate with a doped aluminum oxide bonding layer after a chemical mechanical planarization process in accordance with some embodiments of the present principles.

FIG. 8 depicts a cross-sectional view of a substrate in preparation for a hybrid bonding process in accordance with some embodiments of the present principles.

FIG. 9 depicts a cross-sectional view of a substrate with an aluminum oxide bonding layer in accordance with some embodiments of the present principles.

FIG. 10 depicts a cross-sectional view of a metal contact formed through an aluminum oxide bonding layer in accordance with some embodiments of the present principles.

FIG. 11 depicts a cross-sectional view of an aluminum oxide bonding layer being doped with a metal dopant in a global doping process in accordance with some embodiments of the present principles.

FIG. 12 depicts a cross-sectional view of a selective doping process of an aluminum oxide bonding layer in accordance with some embodiments of the present principles.

FIG. 13 depicts a cross-sectional view of a substrate with a doped aluminum oxide bonding layer after a chemical mechanical planarization process in accordance with some embodiments of the present principles.

FIG. 14 depicts cross-sectional views of a hybrid bonding process without a doped aluminum oxide bonding layer of the present principles.

FIG. 15 depicts cross-sectional views of a hybrid bonding process using a doped aluminum oxide bonding layer in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide improved hybrid bonding performance by doping aluminum oxides deposited as a bonding surface. The doped aluminum oxide layer prevents migration of aluminum oxide over copper contacts during annealing of the bonded substrates, providing both high dielectric and contact bonding strengths. The high bonding strengths provided by the present methods enable increased metal contact densities to be achieved, allowing for scaling of semiconductor devices. The present techniques may be performed prior to contact formation on a substrate or after contact formation on the substrate, providing processing flexibility and easy integration into existing hybrid bonding preparation processes.

Traditional dielectrics such as silicon dioxide limit the scaling of devices due to the bonding strength of the dielectric material. In order to increase the metal contact densities, the bonding strength of the dielectrics used in hybrid bonding must be increased as the bonding strength of the metal contacts is relatively low compared to the dielectric bonding strength. Aluminum oxide is being considered as a replacement for dielectric materials such as silicon dioxide. Aluminum oxide has a 40% to 80% increase in bonding strength compared to that of silicon dioxide. However, the inventors have found that when a substrate with aluminum oxide and metal contacts are bonded together and then annealed, the aluminum oxide migrates over the top surfaces of the metal contacts and prevents the metal contacts from bonding. The inventors believe that the migration of the aluminum oxide is caused by low-temperature crystallization of the aluminum oxide. Typically, aluminum oxide crystallizes at a temperature of approximately 850 degrees Celsius. Hybrid bonding annealing temperatures are generally around 350 degrees Celsius. The inventors believe that the crystals of the metal material (e.g., copper, etc.) of the metal contacts acts as a catalyst for the crystallization of the aluminum oxide which lowers the crystallization temperature to at or below the annealing temperature. The low temperature causes the aluminum oxide to crystallize and migrate/diffuse over the surfaces of the metal contacts during annealing of the bonded substrate (e.g., the aluminum oxide has a higher diffusion rate than copper at a given temperature causing aluminum oxide to migrate).

The inventors found that to successfully bond using an aluminum oxide bonding layer, the aluminum oxide crystallization and subsequent migration need to be prevented. Suppression of the aluminum oxide crystallization during hybrid bonding may be accomplished by doping the aluminum oxide with a crystal-suppressing element or by disrupting the aluminum oxide crystal lattice. Any element that suppresses crystallization of aluminum oxide is suitable. For example, elements that do not easily fit in the lattice points of aluminum or oxygen in aluminum oxide, such as, but not limited to, hafnium and the like may be used to suppress aluminum oxide crystallization. The inventors found that by doping the aluminum oxide with such an element, the migration of the aluminum oxide does not occur during hybrid bonding anneal processes. The dopant can be implanted on the entire substrate, including into surfaces of the metal contacts, or selective only into the aluminum oxide, as long as the dopant does not make the aluminum oxide conductive or interfere with the metal contact expansion and bonding. Alternatively, the dopant can be deposited in conjunction with the aluminum oxide to form a doped aluminum oxide in a single deposition process.

The doping may be performed by using a plasma treatment process, a thermal treatment process, an ion bombardment process, an alloy deposition process (aluminum oxide plus dopant deposited at the same time) (e.g., ALD or co-sputtering, etc.), and the like. Dopants may include elements with an atomic radius much greater than aluminum or oxygen (such as, e.g., Hf, Zr, Ti, W, Ta) or much smaller than aluminum or oxygen to disrupt the crystal lattice by altering the size or shape of bonds in the region. Dopants that include elements which form different crystal structures than aluminum oxide (Al₂O₃) may also be used for crystallization suppress of the aluminum oxide. The aluminum oxide doping suppresses the grain nucleation (location at which crystal growth begins) by using elements that disrupt the aluminum crystal lattice to prevent the crystallization at low temperatures (approximately 300 degrees Celsius to approximately 400 degrees Celsius). For example, monoclinic lattice structures can be used to disrupt the crystal lattice structure of the aluminum oxide. Adjustments can be made to the dopant concentration and the annealing temperature to produce a doped aluminum oxide bonding layer with suppressed crystallization and migration characteristics. Having the metal dopant interspersed throughout the aluminum oxide layer is preferred as subsequent chemical mechanical planarization (CMP) processes may remove some portions of the aluminum oxide layer. If doping is shallow, a significant portion of the doping may be removed during the planarization process, reducing the crystallization suppression performance of the doped aluminum oxide.

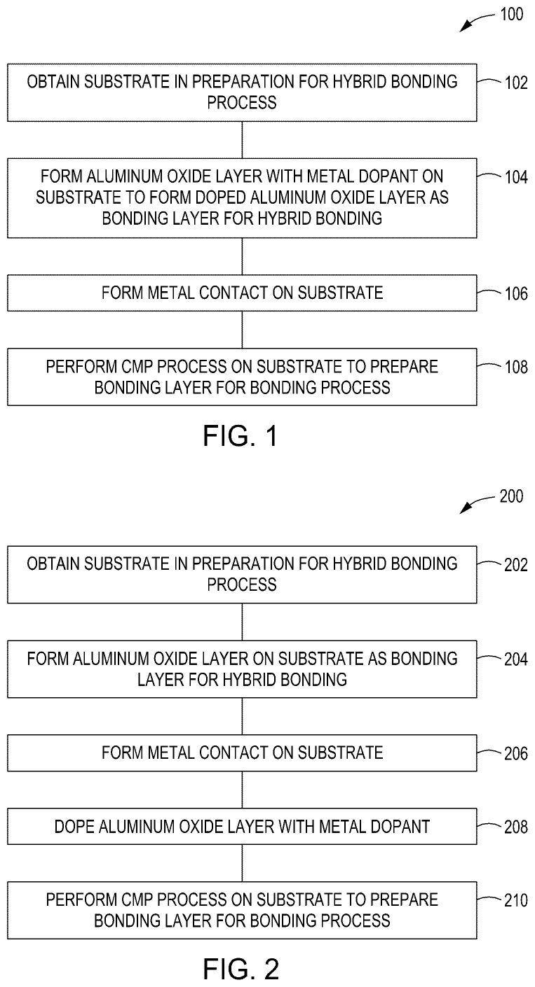

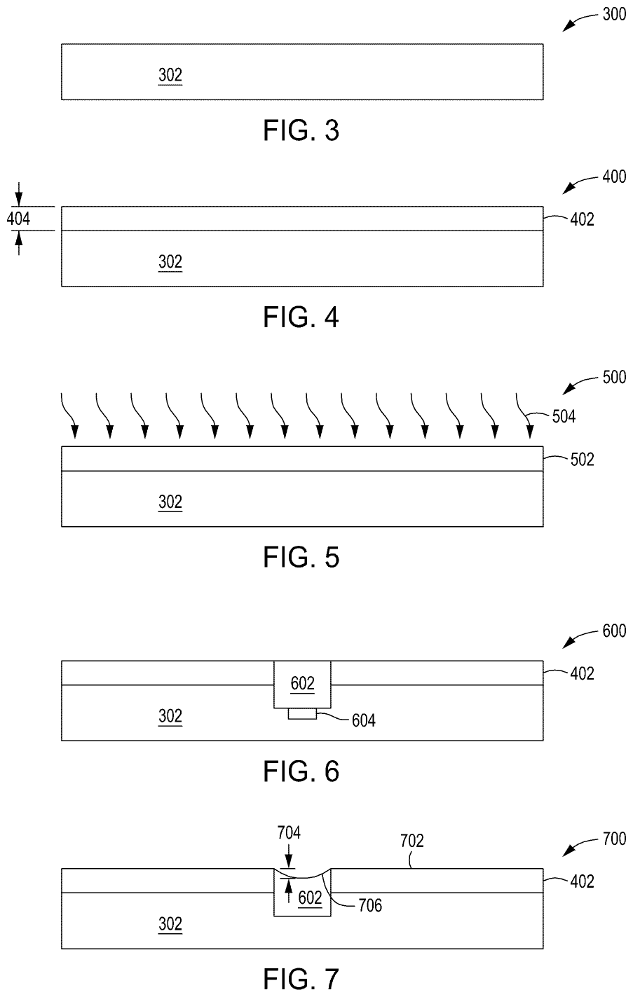

FIG. 1 is a method 100 for preparing a substrate 302 for hybrid bonding. References will be made to FIGS. 3-7 during the discussion of the method 100. In block 102, a substrate is obtained or provided in preparation for the hybrid bonding process as depicted in a view 300 of FIG. 3. The substrate 302 may be formed, at least in part, of dielectric materials such as, for example but not limited to, silicon dioxide and/or silicon carbon nitride materials and the like. In some embodiments, the substrate 302 may have undergone prior device manufacturing and/or packaging processes to prepare the substrate 302 for bonding to another substrate and/or die. In block 104, an aluminum oxide layer with a metal dopant is formed on the substrate 302 to form a doped aluminum oxide layer 402 as a bonding layer for a hybrid bonding process as depicted in a view 400 of FIG. 4. The doped aluminum oxide layer 402 may have a thickness 404 of approximately 30 nm to approximately 50 nm.

In some embodiments, the amount of dopant and processes used for doping are selected to ensure that the leakage current of the doped aluminum oxide layer 402 is less than approximately 2× (two times) that of aluminum oxide or silicon dioxide while still suppressing the crystallization of the aluminum oxide. The metal dopant is conductive in nature to varying degrees, and the conductivity of the metal dopant is taken into account to determine the amount of doping that ensures suppression of crystallization of the aluminum oxide while also ensuring that the doped aluminum oxide layer 402 still serves as an insulative dielectric on the surface of the substrate 302. In some embodiments, the leakage current of the doped aluminum oxide layer 402 may be approximately 100 nA/cm² or less.

Formation of the doped aluminum oxide layer 402 prior to formation of the metal contacts on the substrate 302 allows the doping process to use oxygen during the doping process without forming oxides on the metal contacts. The oxygen can be used to control the leakage current of the doped aluminum oxide layer 402 by mitigating the conductivity of the metal dopant as the doped aluminum oxide layer 402 is formed. Oxygenating the doping process minimizes the leakage current issue significantly, as the aluminum oxide will remain an insulator after doping. Without having to control the leakage current, the sole focus becomes suppression of the crystallization of the aluminum oxide, allowing higher concentrations of the metal dopant to be used to ensure that the migration of the aluminum oxide does not occur during annealing (e.g., 50% metal dopant (or higher) and 50% aluminum oxide (or less), etc.).

As the metal contacts on the substrate 302 promote crystallization and migration of the aluminum oxide at much lower temperatures (aluminum oxide crystallizes at 850 degrees Celsius and inventors have observed crystallization of aluminum oxide at less than 400 degrees Celsius during hybrid bonding annealing), the amount of metal dopant may be selected based on the temperature of the annealing processes that are performed after the bonding process of a hybrid bonding procedure. In some embodiments, the doped aluminum oxide layer may contain at least approximately 25% metal dopant to prevent crystallization of the aluminum oxide. In some embodiments, the doped aluminum oxide layer may contain at least approximately 50% metal dopant. As higher temperatures promote crystallization, annealing temperatures of approximately 300 degrees Celsius may require lower amounts of metal dopants and annealing temperatures of approximately 350 degrees or higher may require higher amounts of dopants to prevent crystallization of the aluminum oxide. The amount of metal dopant used is based on the temperatures used in the hybrid bonding annealing procedures and the leakage current requirements (where leak current is applicable-oxygenated (not applicable), nonoxygenated (applicable) doping processes) to keep the doped aluminum oxide layer 402 insulative.

Some metal dopants have higher conductivity than other metal dopants and drive the leakage current higher with lower amounts of dopant. As such, higher conductivity may cause too high of a leakage current at a given amount of dopant which is not sufficient to suppress the crystallization of the aluminum oxide at a given annealing temperature. Thus, the type of dopant, due to the dopant's conductivity, may need to be altered based on the leakage and crystallization suppression characteristics for a given annealing temperature. In general, the higher the metal dopant concentration, the higher the crystallization temperature of the aluminum oxide. However, the higher metal dopant concentrations are limited by the acceptable leakage current characteristics of a given application (which can change based on the application). Formation of the doped aluminum oxide layer using oxygen can eliminate the leakage current from the doping equation.

Aluminum oxide has a 40% to 80% increased bonding strength over the silicon dioxide of the substrate 302. An aluminum oxide layer would provide a substantial improvement when used as a bonding layer if not for migration of the aluminum oxide during subsequent annealing processes of a hybrid bonding process. The present methods incorporate the doped aluminum oxide layer 402 to overcome the deficiencies of the aluminum oxide while providing all or at least a substantial portion of the increased bonding strength of the aluminum oxide over silicon dioxide and the like. In some embodiments, the doped aluminum oxide layer 402 is formed by co-sputtering aluminum oxide in conjunction with the metal dopant (and, optionally, oxygen) such that the metal dopant is interspersed throughout the doped aluminum oxide layer 402. In some embodiments, the doped aluminum oxide layer 402 is formed by an atomic layer deposition (ALD) process that includes precursors for the aluminum oxide layer formation in conjunction with precursors for the metal dopant (and, optionally, oxygen) such that the metal dopant is interspersed through the doped aluminum oxide layer 402.

In some embodiments, in the alternative, an aluminum oxide layer 502 is first deposited on the substrate 302 and then a doping process 504 is used to dope the aluminum oxide layer 502 to form the doped aluminum oxide layer 402 as depicted in a view 500 of FIG. 5. The aluminum oxide layer may be doped using a plasma-based doping process, a thermal-based doping process, or an ion bombardment-based doping process, and the like. Oxygen may be introduced during the doping process. As discussed above, the metal dopant has a metal dopant atomic radius greater than an atomic radius of aluminum or oxygen to facilitate in suppressing crystallization of the aluminum oxide in the doped aluminum oxide layer 402. In some embodiments, the metal dopant may be hafnium, zirconium, titanium, tungsten, or tantalum, and the like. The size of the metal dopant helps to suppress the formation of the crystallization of the aluminum oxide during annealing which prevents the migration of the aluminum oxide over the metal contacts.

In block 106, a metal contact 602 is formed into the doped aluminum oxide layer 402 as depicted in a view 600 of FIG. 6. The metal contact 602 penetrates through the doped aluminum oxide layer 402 to make contact with underlying interconnects 604 and the like. The doped aluminum oxide layer 402 and the metal contact 602 form a hybrid bonding layer. In block 108, a CMP process is performed on the substrate 302 as depicted in a view 700 of FIG. 7. The CMP process planarizes the uppermost surface 702 of the substrate 302 and is configured to recess 704 or dish the uppermost surface 706 of the metal contact 602 below the uppermost surface 702 of the doped aluminum oxide layer 402. The recess 704 of the metal contact 602 allows for expansion of the metal contact 602 during annealing processes of the hybrid bonding process. The substrate 302 is then bonded to a similarly prepared substrate and/or die by bringing the uppermost surface 702 of the substrate 302 into contact with another doped aluminum oxide layer on another substrate or die. The bonded substrates are then annealed to further increase the bonding strength of the doped aluminum oxide layers and to bond the metal contacts to one another. The annealing process typically is performed at a temperature of approximately 300 degrees Celsius to approximately 400 degrees Celsius. As the bonding process is a back end of line (BEOL) process, the semiconductor devices on the substrate have a thermal budget that typically cannot substantially exceed 400 degrees Celsius.

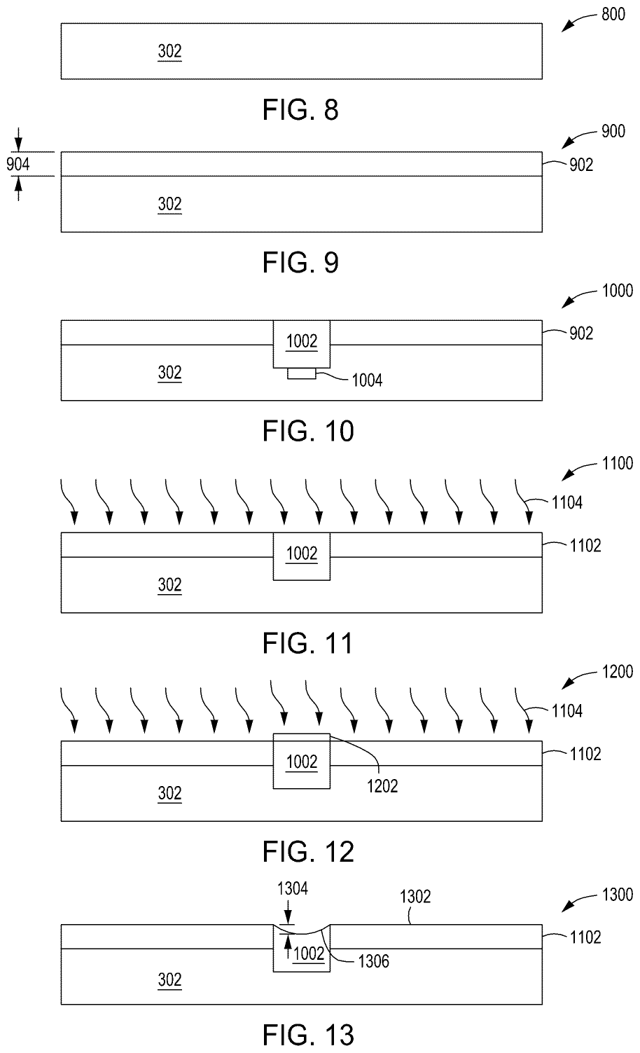

In some instances, the order in which the doping of the substrate 302 occurs may be altered. FIG. 2 is a method 200 for preparing the substrate 302 for hybrid bonding. References will be made to FIGS. 8-13 during the discussion of the method 200. In block 202, the substrate 302 is obtained in preparation for the hybrid bonding process as depicted in a view 800 of FIG. 8. The substrate 302 may be formed, at least in part, of silicon dioxide materials. In some embodiments, the substrate 302 may have undergone prior device manufacturing and/or packaging processes to prepare the substrate 302 for bonding to another substrate and/or die. In block 204, an aluminum oxide layer 902 is formed on the substrate 302 as a dielectric bonding layer for a hybrid bonding process as depicted in a view 900 of FIG. 9. The aluminum oxide layer 902 may have a thickness 904 of approximately 30 nm to approximately 50 nm. In block 206, a metal contact 1002 is formed into the aluminum oxide layer 902 as depicted in a view 1000 of FIG. 10. The metal contact 1002 penetrates through the aluminum oxide layer 902 to make contact with underlying interconnects 1004 and the like.

In block 208, the aluminum oxide layer 902 is doped 1104 with a metal dopant to form a doped aluminum oxide layer 1102 as depicted in a view 1100 of FIG. 11. The doped aluminum oxide layer 1102 and the metal contact 1002 form a hybrid bonding layer. In some embodiments, the metal dopant is implanted in both the aluminum oxide layer 902 and into the metal contact 1002. The metal dopant, being conductive, does not directly impact the conductivity of the metal contact 1002. Care must be taken to avoid affecting the bonding of the metal contact 1002 during the annealing process of the hybrid bonding procedure. The amount of metal dopant is typically insufficient to affect bonding performance of the metal contact 1002, as the metal material of the metal contact (e.g., copper and the like) still has sufficiently large numbers of atoms that far exceed the dopant amounts. The advantage of globally doping the surface of the substrate 302 is that the process is quicker and easier to accomplish than with selective doping processes discussed next. The disadvantage is that oxygen cannot be introduced in the doping process to control the leakage current due to oxides forming on the exposed metal contacts.

In some embodiments, as depicted in the view 1200 of FIG. 12, the metal dopant is implanted only in the aluminum oxide layer 902 and not in the metal contact 1002. The selective doping may be accomplished through photolithography and the like. A photoresist layer 1202 may be patterned on the surface of the metal contact 1002 to prevent doping of the metal contact 1002. Selective doping avoids the issues as discussed above for global doping but requires extra processing for the photolithography and the like. The advantage of selective doping is reactions to the dopant in the metal contact 1002 is not an issue and, therefore, does not impact the type or quantity of dopant that may occur due to the dopant's influence on the bonding properties of the metal contact 1002. In addition, oxygen can be introduced during the doping process to eliminate the leakage current of the aluminum oxide as the metal contact 1002 is not exposed to the oxygen, which would oxidize the metal material of the metal contact 1002 and negatively impact the metal contact's conductivity.

In block 210, similar to block 108 of method 100, a CMP process is performed on the substrate 302 as depicted in a view 1300 of FIG. 13. The CMP process planarizes the uppermost surface 1302 of the substrate 302 and is configured to recess 1304 or dish the uppermost surface 1306 of the metal contact 1002 below the uppermost surface 1302 of the doped aluminum oxide layer 1102. The recess 1304 of the metal contact 1002 allows for expansion of the metal contact 1002 during annealing processes of the hybrid bonding process. The substrate 302 is then bonded to a similarly prepared substrate and/or die (by method 100 or by method 200 and similar) by bringing the uppermost surface 1302 of the substrate 302 into contact with another doped aluminum oxide layer on another substrate or die. The bonded substrates are then annealed to further increase the bonding strength of the doped aluminum oxide layers and to bond the metal contacts to one another. The annealing process typically is performed at a temperature of approximately 300 degrees Celsius to approximately 400 degrees Celsius. As the bonding process is a BEOL process, the semiconductor devices on the substrate have a thermal budget that typically cannot substantially exceed 400 degrees Celsius.

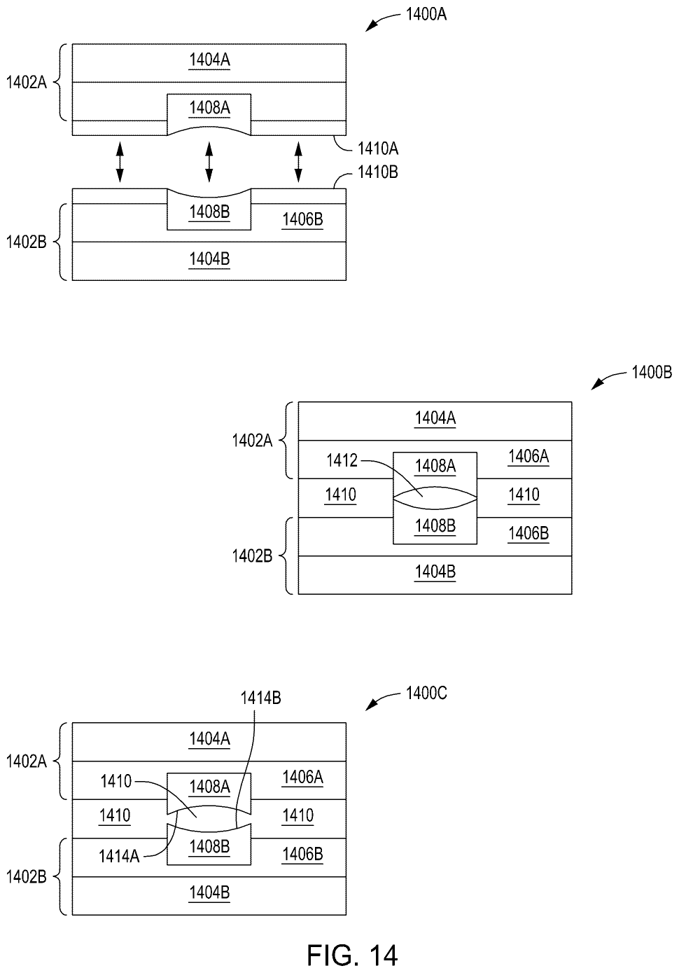

The above methods can be used to enhance the bonding strength and yield of hybrid bonding processes. For example, as depicted in a view 1400A of FIG. 14, the substrates 1402A, 1402B may be bonded together. The substrates 1402A, 1402B have silicon layers 1404A, 1404B, silicon dioxide layers 1406A, 1406B, and metal contacts 1408A, 1408B. The bonding layers are aluminum oxide layers 1410A, 1410B. As depicted in a view 1400B of FIG. 14, when the substrates 1402A, 1402B with aluminum oxide layers 1410A, 1410B are brought into contact with each other (bonded), the aluminum oxide layers 1410A, 1410B form a single aluminum oxide bonded layer 1410. The metal contacts 1408A, 1408B have not yet bonded together, and a gap 1412 exists between the metal contacts 1408A, 1408B due to the recesses formed on each metal contact during CMP processing. In order to close the gap 1412 and form a continuous contact, the substrates 1402A, 1402B undergo an annealing process at temperatures up to 400 degrees Celsius.

The inventors have found that during the annealing process, the aluminum oxide material of the aluminum oxide layers crystallize at a dramatically lower temperature (at 400 degrees Celsius or less compared to a normal crystallization temperature of 850 degrees Celsius) due to the material (e.g., copper, etc.) of the metal contacts acting as a crystallization catalyst. As depicted in a view 1400C of FIG. 14, the substantially lowered crystallization temperature allows the single aluminum oxide bonded layer 1410 to crystallize and migrate over the surfaces 1414A, 1414B of the metal contacts 1408A, 1408B during the annealing process, preventing the metal contacts 1408A, 1408B from bonding together.

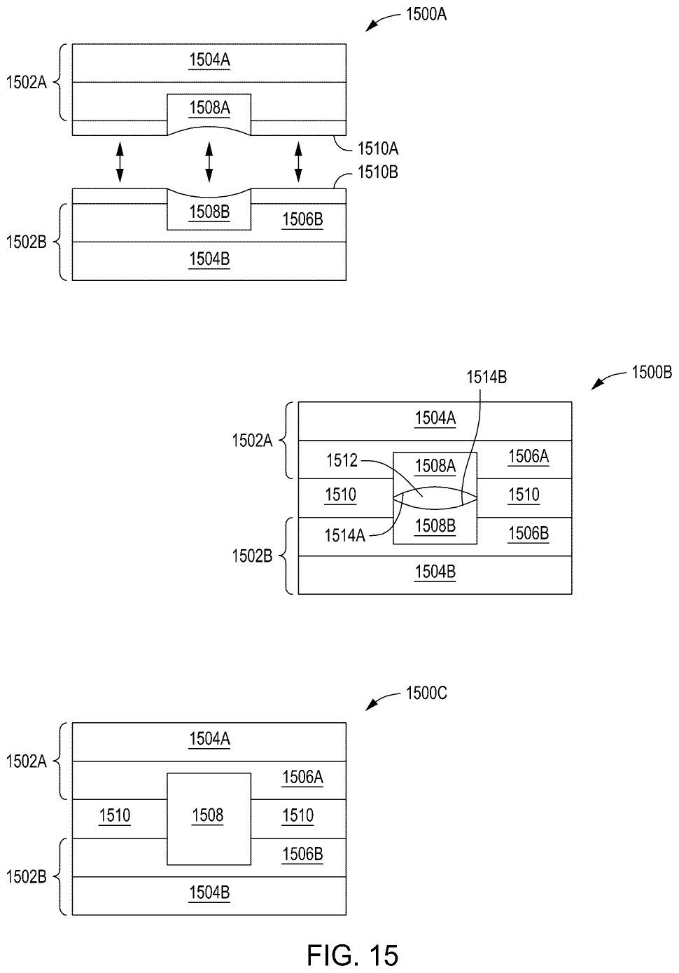

As depicted in a view 1500A of FIG. 15, the substrates 1502A, 1502B may be bonded together using the present methods as described above. In some embodiments, the substrates 1502A, 1502B may include dielectric layers such as, but not limited to, silicon dioxide and/or silicon carbon nitride and the like. In the example, the substrates 1502A, 1502B have silicon layers 1504A, 1504B, silicon dioxide layers 1506A, 1506B, and metal contacts 1508A, 1508B. The bonding layers are doped aluminum oxide layers 1510A, 1510B. As depicted in a view 1500B of FIG. 15, when the substrates 1502A, 1502B with doped aluminum oxide layers 1510A, 1510B are brought into contact with each other (bonded), the doped aluminum oxide layers 1510A, 1510B form a single doped aluminum oxide bonded layer 1510. The metal contacts 1508A, 1508B have not yet bonded together, and a gap 1512 exists between the metal contacts 1508A, 1508B due to the recesses formed on each metal contact during CMP processing. In order to close the gap 1512 and form a continuous contact, the substrates 1502A, 1502B undergo an annealing process at temperatures up to approximately 400 degrees Celsius.

The inventors discovered that by doping the aluminum oxide prior to the annealing process, the aluminum oxide material of the doped aluminum oxide layers did not crystallize at the lower annealing temperatures (at approximately 300 degrees Celsius to approximately 400 degrees Celsius) in spite of the contact material (e.g., copper, etc.) of the metal contacts acting as a crystallization catalyst. As depicted in a view 1500C of FIG. 15, the single doped aluminum oxide bonded layer 1510 does not crystallize and migrate over the surfaces 1514A, 1514B of the metal contacts 1508A, 1508B during the annealing process, allowing the metal contacts 1508A, 1508B to bond together to form a continuous interconnect 1508.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for processing a substrate, comprising:
providing a first substrate for a hybrid bonding process; and
forming, on the first substrate, a hybrid bonding layer that comprises:
a doped aluminum oxide (Al₂O₃) layer; and
a metal contact penetrating through the doped aluminum oxide layer.

2. The method of claim 1, further comprising:
hybrid bonding the first substrate to a second substrate via the hybrid bonding layer.

3. The method of claim 1, wherein the doped aluminum oxide layer is doped with a metal dopant that has an atomic radius greater than an atomic radius of aluminum or oxygen.

4. The method of claim 3, wherein formation of the doped aluminum oxide layer includes depositing an aluminum oxide layer in conjunction with the metal dopant.

5. The method of claim 4, wherein aluminum oxide and the metal dopant are co-sputtered using a physical vapor deposition (PVD) process to form the doped aluminum oxide layer with the metal dopant interspersed throughout.

6. The method of claim 4, wherein aluminum oxide and the metal dopant are deposited using an atomic layer deposition (ALD) process to form the doped aluminum oxide layer with the metal dopant interspersed throughout.

7. The method of claim 3, wherein the metal dopant is hafnium, zirconium, titanium, tungsten, or tantalum.

8. The method of claim 3, wherein an amount of the metal dopant in the doped aluminum oxide layer is selected based on a temperature of an annealing process to be performed after a bonding process.

9. The method of claim 1, wherein the doped aluminum oxide layer is an aluminum oxide layer that is formed first on the first substrate followed by a formation of the metal contact on the first substrate which penetrates through the aluminum oxide layer and then doped with a metal dopant throughout.

10. The method of claim 9, wherein doping of the aluminum oxide layer is performed selectively only on the aluminum oxide layer.

11. The method of claim 9, wherein doping of the aluminum oxide layer is performed on the aluminum oxide layer and on the metal contact.

12. The method of claim 1, wherein the doped aluminum oxide layer is approximately 30 nm to approximately 50 nm in thickness.

13. The method of claim 1, wherein the doped aluminum oxide layer has a leakage current of less than approximately 2× a leakage current of aluminum oxide or silicon dioxide.

14. The method of claim 1, wherein the doped aluminum oxide layer contains at least approximately 25% metal dopant.

15. A substrate prepared for hybrid bonding, comprising:
a dielectric material;
at least one metal contact; and
a doped dielectric bonding layer surrounding the at least one metal contact, wherein an uppermost surface of the at least one metal contact is exposed through the doped dielectric bonding layer.

16. The substrate of claim 15, wherein the doped dielectric bonding layer is a doped aluminum oxide (Al₂O₃) layer, wherein at least one of the at least one metal contact is copper, and wherein the doped aluminum oxide layer is doped with a metal dopant throughout.

17. The substrate of claim 16, wherein the metal dopant is hafnium, zirconium, titanium, tungsten, or tantalum.

18. A device, comprising:
the substrate of claim 15; and
another substrate that is hybrid bonded to the substrate via the doped dielectric bonding layer and the at least one metal contact.

19. A non-transitory, computer readable medium having instructions stored thereon that, when executed, cause a method for processing a substrate, the method comprising:
providing a substrate for a hybrid bonding process; and
forming, on the substrate, a hybrid bonding layer that comprises:
a doped aluminum oxide (Al₂O₃) layer; and
a metal contact penetrating through the doped aluminum oxide layer.

20. The non-transitory, computer readable medium of claim 19, wherein the method further comprises (a), (b), (c), or (d):
a) wherein the doped aluminum oxide layer has a leakage current of less than approximately 2× a leakage current of aluminum oxide or silicon dioxide;
b) wherein the doped aluminum oxide layer is doped with a metal dopant and wherein an amount of the metal dopant in the doped aluminum oxide layer is selected based on a temperature of an annealing process to be performed after a bonding process;
c) wherein formation of the doped aluminum oxide layer includes depositing an aluminum oxide layer on the substrate and then doping the aluminum oxide layer with a metal dopant; or
d) wherein formation of the doped aluminum oxide layer includes depositing an aluminum oxide layer in conjunction with a metal dopant.
